(19) United States
(12) Patent Application Publication
(10) Pub. No.: US 2025/0189461 A1
(43) Pub. Date: Jun. 12, 2025

(54) TEST METHOD FOR A WAFER AND WAFER

(71) Applicant: United Microelectronics Corp., Hsinchu (TW)

(72) Inventor: Ying TONG, Singapore (SG)

(21) Appl. No.: 18/414,488

(22) Filed: Jan. 17, 2024

(30) Foreign Application Priority Data
Dec. 7, 2023 (TW) 112147652

(51) Int. Cl. G01N 21/95; H01L 21/66

(52) U.S. Cl. CPC G01N 21/9505; H01L 22/12; H01L 22/20

(57) ABSTRACT

A test method for a wafer is provided. First, data of an optical characteristic of a test key of the wafer is acquired using an optical scatterometer. The wafer has chip areas and a frame area surrounding and separating the chip areas. The test key is disposed in the frame area. Then, the data is compared with corresponding data of a standard sample without a crack, and a difference between the data and the corresponding date is obtained. It is determined that a crack is formed in the test key and a crack condition in the chip areas does not meet a criterion of the wafer when the difference is larger than a tolerance. It is determined that the crack condition in the chip areas meets the criterion of the wafer when the difference is smaller than or equal to the tolerance.

This application claims the benefit of Taiwan application Serial No. 112147652, filed on Dec. 7, 2023, the subject matter of which is incorporated herein by reference.

### TECHNICAL FIELD

This disclosure relates to a test method for a wafer and a wafer. More particularly, the disclosure relates to a test method for a wafer with a test key and a wafer with a test key.

### BACKGROUND

As the size of wafer components shrink, cracks are more likely to form and develop. The cracks typically initiate at high stress positions, such as corners formed by features of high aspect ratio and a structure thereunder, and may further develop during the manufacturing processes. Nowadays, these cracks can be examined only through a failure analysis for a fully fabricated wafer without a real time test method. In addition, the failure analysis will lead to wafer scrapping.

### SUMMARY

In the disclosure, a test method for a wafer is provided. The test method is a real time test method for cracks formed in and/or from a passivation layer for a pad. The disclosure also provides a wafer, which can be tested by the test method.

The test method according to the disclosure comprises following steps. First, data of an optical characteristic of a test key of the wafer is acquired using an optical scatterometer. The wafer has chip areas and a frame area surrounding and separating the chip areas. The test key is disposed in the frame area. Then, the data is compared with corresponding data of a standard sample without a crack, and a difference between the data and the corresponding date is obtained. It is determined that a crack is formed in the test key and a crack condition in the chip areas does not meet a criterion of the wafer when the difference is larger than a tolerance. It is determined that the crack condition in the chip areas meets the criterion of the wafer when the difference is smaller than or equal to the tolerance.

The wafer according to the disclosure has chip areas and a frame area surrounding and separating the chip areas. The wafer comprises a test key disposed in the frame area. The test key comprises a plurality of test fin features arranged in parallel. The test fin features have a space equal to a minimum space in the chip areas and a pitch equal to a minimum pitch in the chip areas.

### BRIEF DESCRIPTION OF THE DRAWINGS

FIG. 1A is a flow chart of a test method for a wafer according to the disclosure.

FIG. 1B exemplarily illustrates the test method according to the disclosure.

FIG. 2 exemplarily shows an operation of an optical scatterometer used in test method according to the disclosure.

FIG. 3 exemplarily shows a shifted optical characteristic caused by a crack obtained during the test method according to the disclosure.

FIG. 4A exemplarily shows a top view of a wafer according to the disclosure.

FIG. 4B exemplarily shows a cross sectional view of a portion of a chip area of the wafer according to the disclosure.

FIG. 4C exemplarily shows a cross sectional view of a portion of a frame area of the wafer according to the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

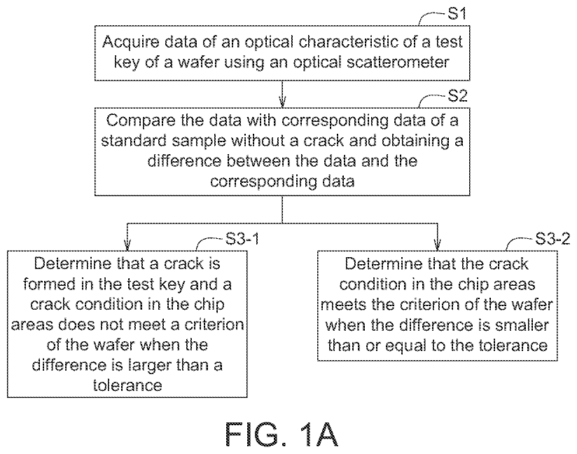

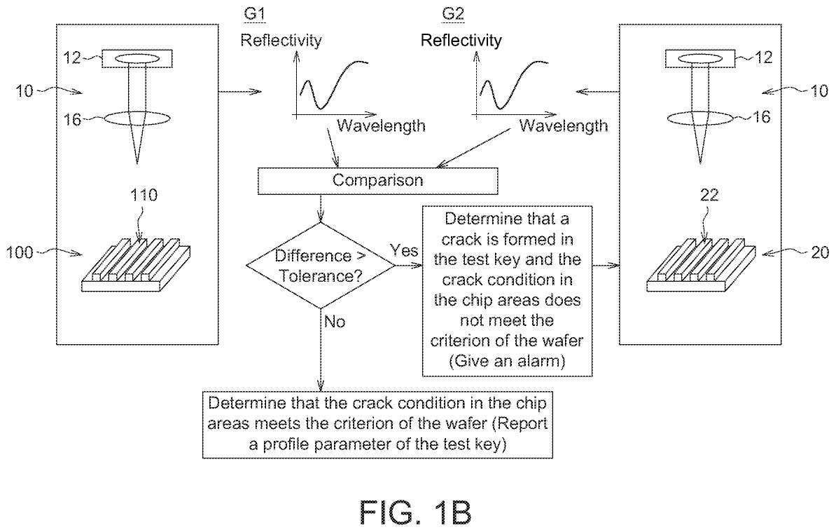

In the disclosure, a test method for a wafer is provided as shown in FIGS. 1A-1B, wherein FIG. 1A is a flowchart of the test method according to the disclosure, and FIG. 1B exemplarily illustrates the test method according to the disclosure.

In step S1, data of an optical characteristic of a test key 100 of a wafer is acquired using an optical scatterometer 10. Specific characteristics of the wafer will be disclosed further below. The wafer has chip areas and a frame area surrounding and separating the chip areas. The test key 100 is disposed in the frame area.

As shown in FIG. 1B, the test key 100 can comprise includes a plurality of test fin features 110 arranged in parallel. The structural characteristics of the test key 100 are determined according to the design rules of the chip areas. For example, a space s of the test fin features 110 can be equal to a minimum space in the chip areas, and a pitch p of the test fin features 110 can be equal to a minimum pitch in the chip areas.

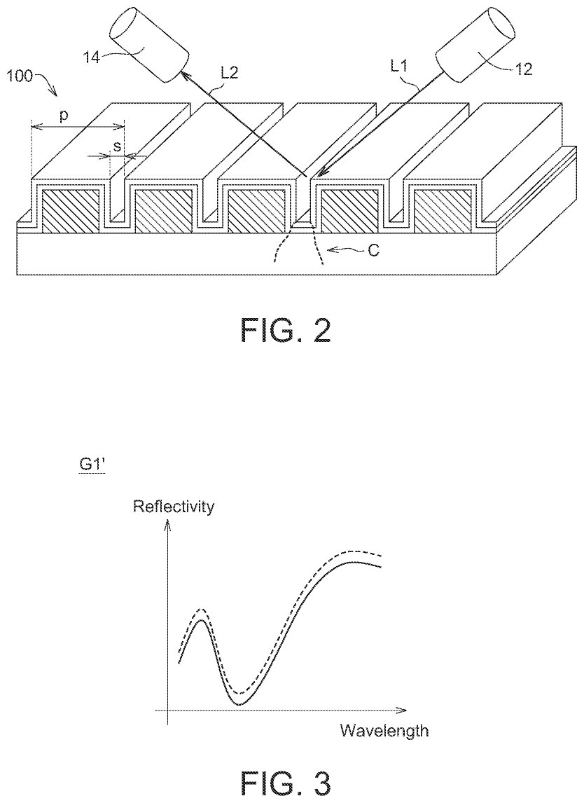

Referring to FIG. 2, an operation of an optical scatterometer 10 is exemplarily shown. The optical scatterometer 10 comprises a light source 12 and a light detector 14, and the optical scatterometer 10 can further comprise any suitable lens assembly (shown in FIG. 1B). Correspondingly, the step S1 using the optical scatterometer 10 can comprise directing light beams L1 incident from the optical scatterometer 10 to the test key 100, and collecting light beams L2 reflected from and/or transmitting through the test key 100 to the optical scatterometer 10. In some embodiments, the step S1 further comprises analyzing the light beams L2 reflected from and/or transmitting through the test key 100 to the optical scatterometer 10. According to some embodiments, the optical characteristic can be variation of reflectivity with wavelength. The data can be plotted as a reflectivity-wavelength graph, as the graph G1 shown in FIG. 1B. Alternatively, the optical characteristic can be variation of reflectivity with incident angles. The data can be plotted as a reflectivity-incident angle graph.

The step S1 is conducted before all manufacturing processes of the wafer are completely completed.

In step S2, the data is compared with corresponding data of a standard sample 20 without a crack, and a difference between the data and the corresponding data is obtained.

As shown in FIG. 1B, the standard sample 20 has a configuration substantially same as a configuration of the test key 100. Specifically, the standard sample 20 can comprise a plurality of sample fin features 22 arranged in parallel, and be formed of same materials and have a same height, a same space, and a same pitch as the test fin features 100.

In some embodiments, the standard sample 20 had been fabricated far before the wafer test method according to the disclosure, and had been confirmed that no cracks are formed therein. Whether there was a crack is formed in the standard sample 20 can be checked through a conventional failure analysis for examining a crack using such as the scanning electron microscope (SEM) or focus ion beam system (FIB). If any cracks were found, a new standard sample 20 would be fabricated. In some embodiments, the test method according to the disclosure further comprises, before the step S1 or the step S2, forming the standard sample 20 having a configuration substantially same as a configuration of the test key 100, and confirming that no crack is formed in the standard sample using at least one of SEM or FIB. If it is confirmed that no crack is formed in the standard sample 20, the optical scatterometer 10 is used to acquire data of said optical characteristic of the standard sample 20, i.e. said corresponding data, in same manner as to obtain the optical characteristic of the test key 100. Similarly, the data can be plotted as a reflectivity-wavelength graph, as the graph G2 shown in FIG. 1B, or a reflectivity-incident angle graph.

As shown in step S3-1, it is determined that a crack is formed in the test key 100 and a crack condition in the chip areas does not meet a criterion of the wafer when the difference is larger than a tolerance.

Since the test key 100 and the chip areas are based on the same design rules, the crack condition in the test key 100 can reflect the crack condition in the chip areas. When the space s of the test fin features 110 is equal to the minimum space in the chip areas and the pitch p of the test fin features 110 is equal to the minimum pitch in the chip areas, a pattern density of the test key 100 is actually higher than a pattern density in the chip areas, and thus a crack is more easy to form in the test key 100.

When a crack C as illustrated by dotted lines in FIG. 2 forms in the test key 100, as shown by the graph G1′ of FIG. 3, the data of the test key 100 (the solid line) is offset from the data of the standard sample 20 without a crack (the dotted line) because the crack formed in the test key 100 results in a stress change at the surface of the test key.

In some embodiments, the difference between the data and the corresponding data is an average value of difference values at a plurality of wavelengths or incidence angles. According to some embodiments, the tolerance can be determined according to a value of goodness of fit (GOF). In some embodiments, the value of goodness of fit is set at, for example, 0.9. However, it should be understood that the value of goodness of fit can be specified according to experimental data according to requirements.

According to some embodiments, when the difference is larger than the tolerance, it is determined that a crack is formed in the test key 100 and the crack condition in the chip areas does not meet the criterion of the wafer, and an alarm is given. The alarm can be given by a warning window. Alternatively, the alarm can be given by a warning light or a warning sound, without particular limit.

When it is determined that the crack condition in the chip areas does not meet the criterion of the wafer, the wafer can be scrapped.

As shown in step S3-2, it is determined that the crack condition in the chip areas meets the criterion of the wafer when the difference is smaller than or equal to the tolerance.

According to some embodiments, when the difference is smaller than or equal to the tolerance, it is determined that the crack condition in the chip areas meets the criterion of the wafer, and a profile parameter of the test key 100 is reported.

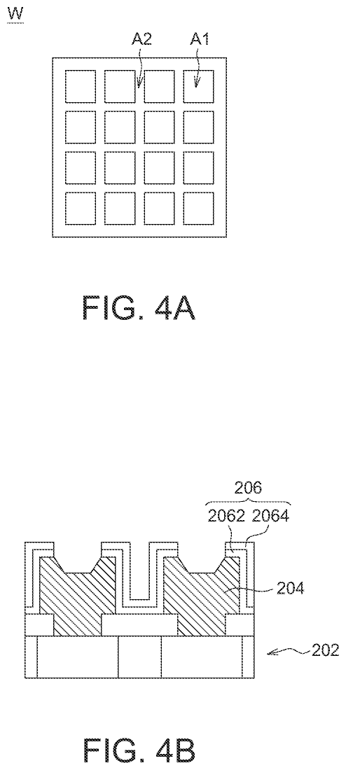

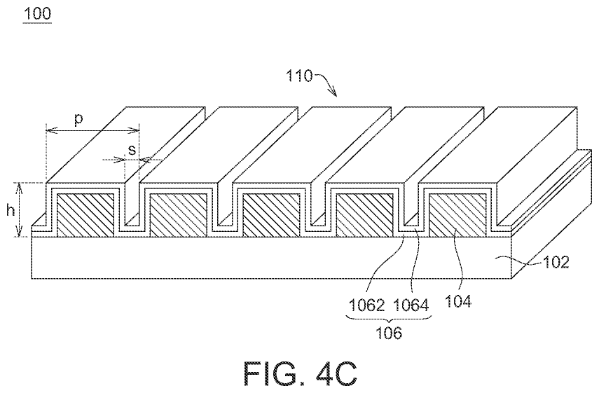

In the disclosure, a wafer is also provided. The wafer can be tested by the test method as described above. FIGS. 4A-4C exemplarily shows a wafer W according to the disclosure, wherein FIG. 4A is a top view of the wafer W, FIG. 4B is a cross sectional view of a portion of a chip area A1 of the wafer W, and FIG. 4C is a cross sectional view of a portion of a frame area A2 of the wafer W.

The wafer W has chip areas A1 and a frame area A2 surrounding and separating the chip areas A1. The wafer W comprises a test key 100 disposed in the frame area A2, as shown in FIG. 4C. The test key 100 comprises a plurality of test fin features 110 arranged in parallel. The test fin features 110 have a space s equal to a minimum space in the chip areas A1. The test fin features 110 have a pitch p equal to a minimum pitch in the chip areas A1.

According to some embodiments as shown in FIG. 4C, the wafer W can further comprise, in the frame area A2, a bottom layer 10, a plurality of conductive fins 104, and a dielectric layer 106. The conductive fins 104 are disposed on the bottom layer 102. The dielectric layer 106 is conformally disposed on the conductive fins 104. Each of the conductive fins 104 and a portion of the dielectric layer 106 covering thereon forms one of the test fin features 110. In some embodiments, the dielectric layer 106 has a multi-layered structure. For example, the dielectric layer 106 can comprise a first dielectric layer 1062 and a second dielectric layer 1064. The second dielectric layer 1064 is disposed on the first dielectric layer 1062.

According to some embodiments, as shown in FIG. 4B, the wafer W can further comprise, in each of the chip areas A1, a main structure 202, pads 204, and a passivation layer 206. The pads 204 are disposed on the main structure 202. The passivation layer 206 is disposed on the pads 204 and the main structure 202 and exposes portions of the pads 204. In some embodiments, the passivation layer 206 can comprise a first passivation layer 2062 and a second passivation layer 2064. The second passivation layer 2064 is disposed on the first passivation layer 2062.

According to some embodiments, the conductive fins 104 and the pads 204 can be formed together by same manufacturing processes, and the dielectric layer 106 and the passivation layer 206 can be formed together by same manufacturing processes. In such a condition, the conductive fins 104 and the pads 204 can be formed of a same material, such as metal. For example, the conductive fins 104 and the pads 204 can be formed of aluminum. The dielectric layer 106 and the passivation layer 206 can be formed of a same material. For example, the dielectric layer 106 and the passivation layer 206 can be formed of a nitride or an oxide. More specifically, the first dielectric layer 1062 and the first passivation layer 2062 can be formed of a nitride. The second dielectric layer 1064 and the second passivation layer 2064 can be formed of an oxide. In addition, the test fin features 110 can have a height h equal to a sum of a thickness of the pads 204 and a thickness of the passivation layer 206.

The test key 100 of the wafer W as described above can reflect the crack condition in the chip areas A1, particularly the condition at the passivation layer 206 and the pads 204 underneath.

In summary, the disclosure provides a test method for a wafer and a wafer that can be tested by the test method. The test method according to the disclosure can achieve real-time monitoring. The test method according to the disclosure is a non-destructive method. Moreover, the test method according to the disclosure is compatible with a baseline process without using an extra mask. The test method according to the disclosure further possesses the advantages of having a high through put rate, a large inspection area, and so on.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A test method for a wafer, comprising:
acquiring data of an optical characteristic of a test key of the wafer using an optical scatterometer, wherein the wafer having chip areas and a frame area surrounding and separating the chip areas, and the test key is disposed in the frame area;
comparing the data with corresponding data of a standard sample without a crack and obtaining a difference between the data and the corresponding date;
determining that a crack is formed in the test key and a crack condition in the chip areas does not meet a criterion of the wafer when the difference is larger than a tolerance; and
determining that the crack condition in the chip areas meets the criterion of the wafer when the difference is smaller than or equal to the tolerance.

2. The test method according to claim 1, wherein acquiring the data of the optical characteristic of the test key of the wafer using the optical scatterometer is conducted before all manufacturing processes of the wafer are completely completed.

3. The test method according to claim 1, wherein acquiring the data of the optical characteristic of the test key of the wafer using the optical scatterometer comprises:
directing light beams incident from the optical scatterometer to the test key; and
collecting light beams reflected from and/or transmitting through the test key to the optical scatterometer.

4. The test method according to claim 3, wherein acquiring the data of the optical characteristic of the test key of the wafer using the optical scatterometer further comprises:
analyzing the light beams reflected from and/or transmitting through the test key to the optical scatterometer.

5. The test method according to claim 1, wherein the optical characteristic is variation of reflectivity with wavelength.

6. The test method according to claim 1, wherein the data is plotted as a reflectivity-wavelength graph.

7. The test method according to claim 1, wherein the test key comprises a plurality of test fin features arranged in parallel, the test fin features having a space equal to a minimum space in the chip areas and a pitch equal to a minimum pitch in the chip areas.

8. The test method according to claim 1, wherein the difference is an average value of difference values at a plurality of wavelengths or incidence angles.

9. The test method according to claim 1, wherein the tolerance is determined according to a value of goodness of fit.

10. The test method according to claim 1, wherein when the difference is larger than the tolerance, it is determined that a crack is formed in the test key and the crack condition in the chip areas does not meet the criterion of the wafer, and an alarm is given.

11. The test method according to claim 10, wherein the alarm is given by a warning window.

12. The test method according to claim 1, wherein when the difference is smaller than or equal to the tolerance, it is determined that the crack condition in the chip areas meets the criterion of the wafer, and a profile parameter of the test key is reported.

13. The test method according to claim 1, further comprising:
forming the standard sample having a configuration substantially same as a configuration of the test key; and
confirming that no crack is formed in the standard sample using at least one of SEM or FIB.

14. A wafer, having chip areas and a frame area surrounding and separating the chip areas, the wafer comprising:
a test key disposed in the frame area, the test key comprising a plurality of test fin features arranged in parallel, the test fin features having a space equal to a minimum space in the chip areas and a pitch equal to a minimum pitch in the chip areas.

15. The wafer according to claim 14, comprising, in the frame area:
a bottom layer;
a plurality of conductive fins disposed on the bottom layer; and
a dielectric layer conformally disposed on the conductive fins;
wherein each of the conductive fins and a portion of the dielectric layer covering thereon forms one of the test fin features.

16. The wafer according to claim 15, further comprising, in each of the chip areas:
a main structure;
pads disposed on the main structure; and
a passivation layer disposed on the pads and the main structure and exposes portions of the pads;
wherein the conductive fins and the pads are formed of a same material, and the dielectric layer and the passivation layer are formed of a same material.

17. The wafer according to claim 16, wherein the conductive fins and the pads are formed of Al.

18. The wafer according to claim 16, wherein the dielectric layer and the passivation layer are formed of a nitride and an oxide.

19. The wafer according to claim 16, wherein the test fin features have a height equal to a sum of a thickness of the pads and a thickness of the passivation layer.
